(19) United States
(12) Patent Application Publication
(10) Pub. No.: US 2006/0258066 A1
(43) Pub. Date: Nov. 16, 2006

(54) Electrically stabilized integrated circuit

(75) Inventors: Jean-Pierre Schoellkopf, Grenoble (FR); Philippe Roche, Le Versoud (FR); Herve Jaouen, Meylan (FR)

Correspondence Address: SEED INTELLECTUAL PROPERTY LAW GROUP PLLC, 701 FIFTH AVENUE, SUITE 6300, SEATTLE, WA, 98104-7092, US

(73) Assignee: STMicroelectronics SA, Montrouge (FR)

(21) Appl. No.: 11/407,849

(22) Filed: Apr. 20, 2006

(30) Foreign Application Priority Data
Apr. 20, 2005 (FR) 05 03958

(51) Int. Cl. H01L 21/84

(52) U.S. Cl. 438/152

(57) ABSTRACT

An integrated electronic circuit comprises active components disposed on the surface of a substrate and connected by electrical connections disposed within a metallization level. A dielectric material situated between the surface of the substrate and the metallization level, or in the metallization level, has a locally higher value of dielectric permittivity so as to selectively increase a capacitance between certain portions of the active components or of the connections. An electrical state of the circuit in operation is then stabilized, thanks to a higher electrical charge carried by the portions of the active components or of the connections whose capacitance is enhanced. The circuit can be a static random access memory cell.

### BACKGROUND OF THE INVENTION

1. Field of the Invention

The present invention generally relates to an integrated electronic circuit and a fabrication process for such a circuit.

In particular, it relates to a static random access memory or SRAM cell, a fabrication process for the cell, together with a memory array comprising such cells.

2. Description of the Related Art

FIG. 1 is a circuit diagram of an SRAM cell with six MOS (Metal-Oxide-Semiconductor) transistors. The cell comprises two inverters I1 and I2, each connected at its output to an input of the other inverter via an electrical node denoted BLTI or BLFI. The nodes BLTI and BLFI are furthermore respectively connected to bit lines BLT and BLF by access transistors T1 and T2. The gates of the transistors T1 and T2 are connected to the same word line WL.

The inverter I1 comprises two transistors TP1 and TN1, respectively of the pMOS and nMOS type. The gates of the transistors TP1 and TN1 are connected to the cell node BLTI and form the input of the inverter I1. The drains of the transistors TP1 and TN1 are connected to the node BLFI and form the output of the inverter I1. The sources of the transistors TP1 and TN1 are respectively connected to a DC power supply source, denoted VDD, and a voltage reference terminal, denoted GND.

The inverter I2 has a structure that is identical to that of the inverter I1 and comprises the transistors TP2 and TN2.

FIG. 2 is a simplified top view of an embodiment of such an SRAM cell in CMOS (complementary metal-oxide-semiconductor) technology. For reasons of simplicity, the transistors are all shown with the same gate width. The n-channel transistors T1, T2, TN1 and TN2 are fabricated within a p-type substrate, denoted SUB and referenced 100. The p-channel transistors TP1 and TP2 are fabricated within an n-type well embedded in the substrate 100 and denoted NWELL.

According to this embodiment of the SRAM cell, the drain regions of the transistors TN1 and T2 form a common region on the surface of the substrate 100, as do the drain regions of the transistors TN2 and T1. The material of the transistor gates on the surface of the substrate 100, which are the shaded regions in FIG. 2, is polycrystalline silicon. The gates of the transistors TP1 and TN1 are directly connected together by a gate link BLTI. Similarly, the gates of the transistors TP2 and TN2 are also directly connected together by a gate link BLFI. The two gate links BLTI and BLFI thus belong to the transistor gate level on the surface of the substrate 100.

The gate link BLTI is also connected to the drains of the transistors TP2 and TN2 by a section of metal interconnect SPT. The section of interconnect SPT belongs to a first metallization level situated above the gate level. The first metallization level is separated from the surface of the substrate 100 by an intermediate level, also called pre-metallization level, within which the transistor gates are laid. The intermediate and the first metallization levels are formed from layers of electrically insulating dielectric materials, for example silica (SiO₂). In addition to the section of interconnect SPT, voltage supply terminals VDD and voltage reference terminals GND, together with connection terminals for the lines BLT and BLF are formed within the first metallization level at the locations indicated in FIG. 2. These terminals and the section of interconnect SPT are connected to source regions of the cell transistors and to the gate link BLTI by connections running through the intermediate layer in a direction that is substantially perpendicular to the surface of the substrate 100. The locations of these connections are indicated by crosses in FIG. 2.

In the same way, the gate link BLFI is connected to the drains of the transistors TP1 and TN1 by a section of metal interconnect SPF.

For reasons of clarity, the isolation trenches STI (Shallow Trench Isolator) that surround the transistors in the substrate 100 are not shown.

As is shown in FIG. 2, the transistors of the SRAM cell are preferably arranged in a configuration that is symmetric with respect to a central axis A of the cell, perpendicular to the surface of the substrate 100.

FIG. 3 is a cross section of the SRAM cell from FIG. 2 in the plane III-III. In this figure, S0 is the surface of the substrate 100, M0 denotes the intermediate level and M1 denotes the first metallization level. In addition, S10 denotes a stop layer that covers the surface of the substrate 100 and the gates of the transistors. Such a stop layer is known to those skilled in the art and is useful during the formation of the connections through the layer M0. The layer S10 is for example silicon nitride (Si₃N₄). The references 10, 11 and 14 denote electrical connections through the layer M0.

The inverters I1 and I2 form a bistable structure that can take two states. When the access transistors T1 and T2 are switched on by applying an appropriate electrical voltage to the line WL, the state of the inverters I1 and I2 can be programmed by applying a particular control command to the lines BLT and BLF. One piece of binary information, or bit, can thus be recorded in the SRAM cell. When the access transistors T1 and T2 are turned off, the cell then conserves the information in the form of an electrical charge contained in the gate capacitances of the transistors of the inverters I1 and I2.

The MOS transistor SRAM cells fabricated recently have smaller and smaller dimensions. The capacitance of the gates of the transistors of the inverters I1 and I2 is therefore reduced. In addition, the voltage VDD supplying the cell is also decreased. The result of this is that the electrical charges on the gates corresponding to the binary storage state of the cell have become very small. Ionizing radiation that strikes the SRAM cell may then create spurious electrical charges there that are large enough to modify the binary storage state. In other words, the stability of the electrical state of the SRAM cell against the interference caused by ionizing radiation is inadequate.

In order to enhance the stability of the binary storage state of an SRAM cell, it has been proposed to associate a capacitor with each of the gate links BLTI and BLFI, respectively. The nodes of the cell that carry the electrical charges therefore have increased capacitances, such that ionizing radiation is no longer capable of modifying the storage state of the cell. However, the formation of such capacitors requires the inclusion of additional steps in the cell fabrication process, notably lithographic steps. The fabrication process for an SRAM cell equipped with capacitors is therefore complex, and its production cost is high in consequence.

### BRIEF SUMMARY OF THE INVENTION

One embodiment of the invention provides an integrated electronic circuit whose electrical state is more stable, in particular with regard to the interference caused by ionizing radiation, and whose fabrication process may be simplified.

One embodiment of the invention provides an integrated electronic circuit comprising active components disposed on the surface of a substrate and connected by electrical connections disposed within a metallization level situated above the surface of the substrate, in which a dielectric material situated between the surface of the substrate and the metallization level, or in the metallization level, has a locally higher value of dielectric permittivity so as to selectively increase a capacitance between certain portions of the active components or of the connections.

Thus, the capacitance between certain portions of the active components and/or of the connections of the circuit is increased without fabricating a capacitor, but by only modifying the dielectric material within a given region of the circuit. Such a modification of the dielectric material is simple to implement and compatible with a high integration level of the circuit. In particular, the fabrication of metallic capacitor electrodes is not necessary purely in order to increase the capacitances concerned by the invention.

During an operation of the circuit, the portions of the active components or of the connections whose capacitance is increased carry a higher electric charge. The electrical state of the circuit is thus stabilized against the appearance of spurious charges, especially with respect to charges generated by ionizing radiation.

The capacitance increased by using the invention may be present between, on the one hand, a gate of a MOS transistor or a connection linking a gate of a MOS transistor and, on the other hand, another portion of active component or of connection of the circuit. In this case, the modification of the dielectric material can compensate for a decrease in the gate capacitance of the MOS transistor resulting from the reduction in the dimensions of the latter when the circuit integration level is increased.

The local modification of the dielectric material may, for example, comprise a change in the chemical nature of the latter. In this case, the dielectric material locally exhibits a different chemical composition between the portions of the active components or of the connections of the circuit for which the capacitance is increased.

The integrated electronic circuit can comprise a static random access memory cell, which incorporates two access transistors and two inverters. Each inverter has an input comprising a link between respective gates of two MOS transistors of said inverter, and is connected between a voltage reference terminal and voltage supply terminal. The gate link of each inverter is situated at the surface level of the circuit substrate and is connected to a section of interconnect disposed within a metallization layer situated above the surface of the substrate. The section of interconnect is furthermore connected to an output of one of the access transistors and to an output of the other inverter. In addition, each access transistor has an input connected to a bit line and a gate situated at the surface level of the substrate and connected to a word line. An intermediate layer situated between the surface of the substrate and the metallization layer comprises at least a first portion and at least a second portion respectively of a first dielectric material within a first region of the substrate and of a second dielectric material within a second region of the substrate, said first dielectric material having a higher dielectric permittivity than a dielectric permittivity of said second dielectric material. The gate link of each inverter is separated from the voltage reference terminal and from the voltage supply terminal of said inverter, and also from the section of interconnect of the other inverter by respective gaps situated mainly within the first substrate region. Furthermore, the gate and the input of each access transistor are situated within the second substrate region.

Thus, owing to the fact that the respective separation gaps between the gate line of each inverter and the voltage reference and voltage supply terminals, and also between the same gate line and the section of interconnect of the other inverter, are filled with dielectric material of high dielectric permittivity, the input and output nodes of the cell inverters, which are formed by the two gate links, exhibit higher capacitances. Thanks to these higher capacitances, the binary storage state of the cell is not altered by spurious charges created by ionizing radiation striking the SRAM cell. For this reason the SRAM cell is said to be robust.

In addition, given that the input and the gate of each access transistor of the cell are surrounded by material with low dielectric permittivity, the input and output nodes of the cell inverters do not exhibit a significant capacitive interaction with the cell bit and word lines used for control. The bit write and read speeds in an SRAM cell according to one embodiment of the invention are therefore not reduced.

The first dielectric material is advantageously selected from the list comprising alumina (Al₂O₃), barium, strontium and titanium oxide ((Ba,Sr) TiO₃), beryllium aluminum oxide (BeAl₂O₄), cerium oxide (CeO₂), hafnium oxide (HfO₂), hafnium silicate (HfSiO₄), lanthanum oxide (La₂O₃), silicon nitride (Si₃N₄), titanium oxide (TiO₂), tantalum oxide (Ta₂O₅), yttrium oxide (Y₂O₃), zirconium oxide (ZrO₂) and zirconium silicate (SiZrO₄), or is a mixture comprising at least one of the said materials. It therefore exhibits a high dielectric permittivity. At the same time, the second dielectric material can be selected from the list comprising silica (SiO₂), an organic material and a fluorinated material, or may be a mixture comprising at least one of the latter materials. It therefore exhibits a dielectric permittivity that is particularly low.

According to a first improved feature of one embodiment of the invention, the gate link of each inverter is substantially adjacent to the voltage reference terminal and/or to the voltage supply terminal of the said inverter, in a projection onto the surface of the substrate. The capacitance of each node of the cell corresponding to a gate link is then further enhanced, by the effect of the proximity between this gate link and the terminals with which it interacts capacitively. The binary storage state of the SRAM cell is thus even less sensitive to ionizing radiation.

In the same way, each gate link of an inverter is preferably substantially adjacent to the section of interconnect to which the gate link of the other inverter is connected, in a projection onto the surface of the substrate. A similar proximity effect then occurs between the gate links and the sections of interconnect, which also contributes to increasing the capacitances of the nodes of the SRAM cell.

In addition, each voltage reference terminal or voltage supply terminal may comprise a connection that is substantially perpendicular to the surface of the substrate and that runs through the intermediate layer in the first substrate region. The capacitance of each node of the cell that will contain a charge corresponding to the stored bit is then also increased by a contribution resulting from the capacitive interaction between the corresponding gate line and the connections of the voltage reference and voltage supply terminals.

Similarly, complementary contributions to the capacitances of the cell nodes occur when each section of interconnect of an inverter is connected to the output of the corresponding access transistor and to the output of the other inverter by respective connections that are substantially perpendicular to the surface of the substrate and that extend through the intermediate layer in the first substrate region.

According to a second improved feature of one embodiment of the invention, the metallization layer itself comprises a first portion and a second portion respectively of a third dielectric material in the first substrate region and of a fourth dielectric material in the second substrate region, said third dielectric material having a higher dielectric permittivity than a dielectric permittivity of said fourth dielectric material. Another enhanced capacitive interaction then occurs between each section of interconnect and at least one of the voltage reference and/or voltage supply terminals, which contributes to an increase in the capacitance of the cell nodes. The third and fourth dielectric materials can be respectively chosen in the same manner as the first and second dielectric materials.

One embodiment of the invention also provides an array comprising static random access memory cell integrated circuits, such as previously described, disposed next to one another on the surface of a common substrate. The cells are advantageously arranged such that first substrate regions, respectively corresponding to several cells, are contiguous with one another, and so that second substrate regions, respectively corresponding to certain of the cells, are also contiguous with one another. The formation of the metallization layer divided into first and second portions according to the substrate regions is therefore facilitated.

One embodiment of the invention provides an integrated electronic circuit fabrication process that comprises the following steps:

forming active components at a surface level of a semiconductor substrate;

depositing, over the substrate surface, at least one layer of a dielectric material;

locally modifying the dielectric material, so as to selectively increase a capacitance between certain portions of active components or of circuit connections; and

forming the circuit connections.

The modification of the dielectric material may comprise the replacement of a portion of the dielectric material with a portion of another material having a different chemical composition. This replacement is carried out in a region of the dielectric material layer intended to contain, or to be adjacent to, the portions of the active components or of the connections whose capacitance is to be enhanced.

When the integrated electronic circuit comprises a static random access memory cell, the process can comprise the following steps:

forming, on the surface of the semiconductor substrate, MOS transistors of two inverters, two MOS access transistors and, for each inverter, a link connecting gates of the transistors of the said inverter;

forming, over the substrate, a first portion of an intermediate layer in a first region of the substrate so as to at least partially surround the gate links of the transistors of the inverters in a plane parallel to the surface of the substrate, and a second portion of the intermediate layer in a second substrate region so as to at least partially surround gates and inputs of the access transistors, the first and second portions of the intermediate layer being respectively of a first and a second dielectric material, said first dielectric material having a dielectric permittivity that is higher than a dielectric permittivity of said second dielectric material;

forming, through the intermediate layer, connections that are substantially perpendicular to the surface of the substrate and that respectively extend as far as source or drain regions of the transistors or as far as the gate links; and

forming, over the intermediate layer, a metallization layer incorporating two sections of interconnect, each connected to the gate link of the transistors of one of the inverters and to an output of the other inverter, voltage reference and voltage supply terminals, and cell access terminals, so that said sections of interconnect and said terminals are in electrical contact with respective connections of the intermediate layer.

In such a process, the section of interconnect and the voltage reference terminal and voltage supply terminal of each inverter are furthermore disposed within the metallization layer so as to be separated from the gate link of the other inverter by respective gaps situated mainly within the first substrate region. In addition, the cell access terminals are disposed within the metallization layer substantially in a vertical line with the inputs of the access transistors with respect to the surface of the substrate.

The additional steps of such a process which are introduced for the implementation of the invention relate only to the formation of the intermediate layer in two portions made from different materials. The process is therefore not significantly lengthened, such that the production cost of the SRAM cell is substantially unchanged.

According to one preferred embodiment of a process according to the invention, the step for forming the intermediate layer comprises the following sub-steps:

depositing a layer of the second dielectric material over the surface of the substrate in the first and second regions of the substrate;

forming a first mask over the layer of the second dielectric material, said first mask having an opening corresponding to the first substrate region;

removing the second dielectric material in the first region through the opening in the first mask, so that a residual portion of second dielectric material remains in the second substrate region;

forming a portion of the first dielectric material in the first substrate region; and

polishing the respective portions of first and second dielectric materials so that these portions have respective thicknesses that are substantially equal in a direction perpendicular to the surface of the substrate.

The mask used for forming the intermediate layer in two portions of different materials therefore defines the first and second regions of the substrate. Consequently, its pitch is far greater than the width of the gates of the transistors of the SRAM cell. It is therefore not costly to implement, such that it does not lead to any significant increase in the production cost of the SRAM cell.

### BRIEF DESCRIPTION OF THE SEVERAL VIEWS OF THE DRAWINGS

Other features and advantages of the present invention will become apparent in the following description of a non-limiting exemplary embodiment, making reference to the appended drawings, in which:

FIG. 1 is a circuit diagram of an SRAM cell such as is known from the prior art;

FIG. 2 is a top view of an SRAM cell according to the circuit diagram in FIG. 1, fabricated according to the prior art;

FIG. 3 is a cross section of the SRAM cell in FIG. 2 in the plane III-III;

FIG. 4a corresponds to FIG. 2, for two SRAM cells fabricated according to the invention;

FIG. 4b shows a memory array composed of SRAM cells according to the invention;

FIG. 5 is a cross section of the SRAM cells in FIG. 4a in the plane V-V;

FIGS. 6a-6f are cross-sections of the SRAM cells in FIG. 4a in the plane V-V, illustrating various fabrication steps for the cells; and

FIG. 7 illustrates variations of capacitance of the SRAM cell nodes obtained by applying the invention.

### DETAILED DESCRIPTION OF THE INVENTION

The invention is now described in the framework of an integrated static random access memory cell. It will be understood that such an SRAM cell is taken by way of illustration of the invention, but that the invention may be implemented for any type of circuit for which an electrical state of operation is advantageously stabilized.

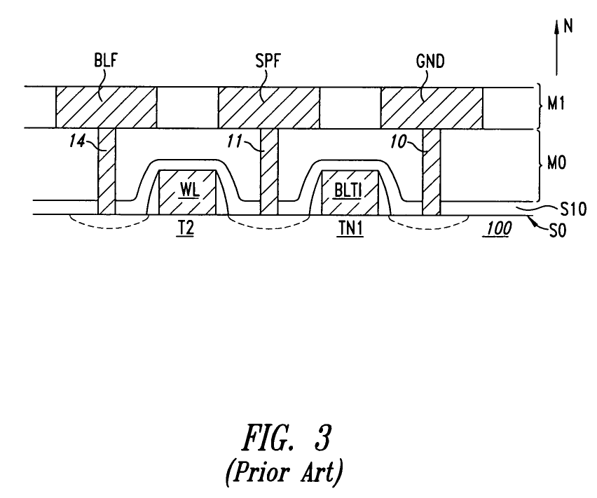

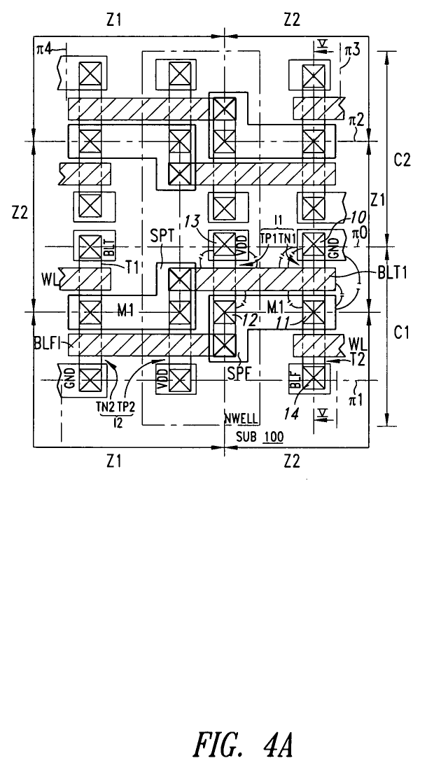

For reasons of clarity, the dimensions of the various elements shown in the figures are not in proportion with real dimensions. In FIGS. 3, 5 and 6a-f, a substantially plane substrate on which one or more SRAM cells are fabricated is placed in the lower part of each figure. N denotes a direction perpendicular to the surface of the substrate, oriented towards the top of the figures. In the following, the terms ‘on’, ‘under’, ‘lower’ and ‘upper’ are used with reference to this orientation. Furthermore, in all the figures, identical references correspond to identical elements.

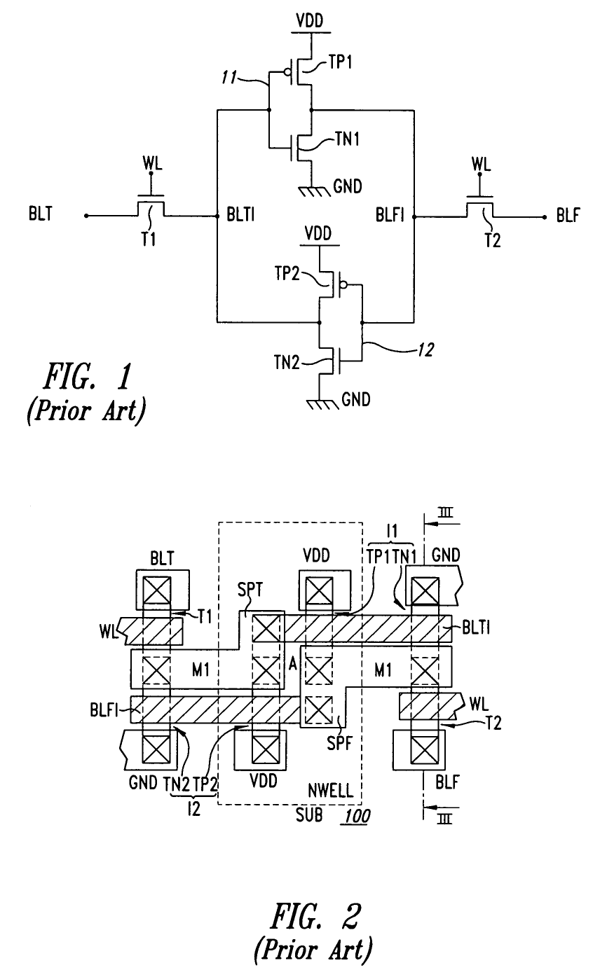

FIGS. 1 to 3 have already been described and are not discussed further.

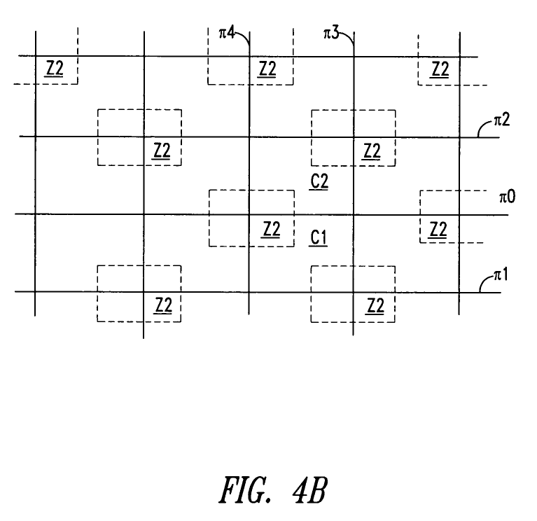

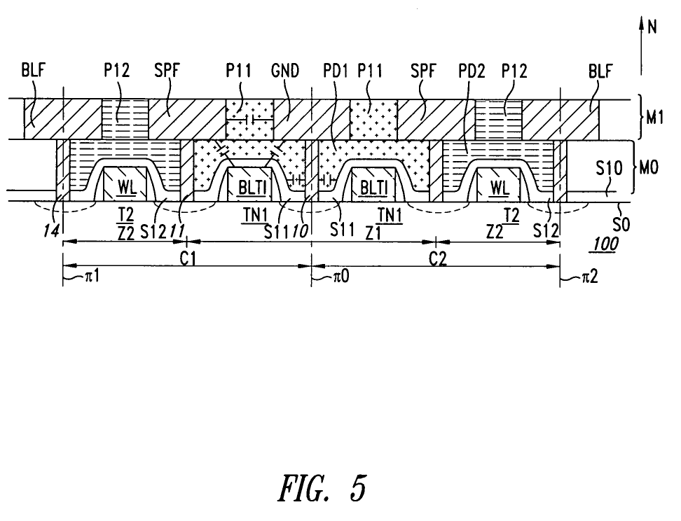

According to FIGS. 4a and 5, two SRAM cells denoted C1 and C2 are formed on a substrate 100 of single-crystal silicon. The transistors and the conducting elements of the cell C1 are disposed in the manner described with reference to FIGS. 1-3. Those of the cell C2 are symmetrically disposed with respect to the corresponding elements of the cell C1, according to a symmetry with respect to the plane Π₀ that is perpendicular to the planes of FIGS. 4 and 5. Thus, the cells C1 and C2 have in common a voltage reference terminal GND and a voltage supply terminal VDD, the source regions of their respective transistors TP1 and TN1, the input of their respective transistors T1, in addition to the corresponding bit line BLT.

Other SRAM cells can also be obtained starting from the cells C1 and C2 by performing symmetry operations with respect to the planes Π₁ and Π₂ indicated in the figures, and with respect to the planes Π₃ and Π₄ that are perpendicular to the planes Π₁ and Π₂, and are situated outside of the cells. A memory array with any given dimensions can therefore be obtained in this way. The following description of the invention is presented for the cells C1 and C2, but it can be extended to the whole of the memory array by applying these symmetry operations.

The substrate 100 is divided into two regions, Z1 and Z2 respectively. Each of these regions Z1, Z2 may be composed of one or more elementary regions for each SRAM cell. In the exemplary embodiment of the invention illustrated by FIGS. 4a and 5, the region Z1 is continuous inside each cell C1, C2, while the region Z2 comprises two rectangles inside each cell. When several SRAM cells are disposed side-by-side on the substrate 100 to form a memory array, the regions Z1 and Z2 extend between adjacent cells. The region Z2 is therefore composed of rectangular islands shared between four neighboring SRAM cells via one of their respective corners, and distributed over a region Z1 that is continuous over the whole surface of the memory array. FIG. 4b is a top view of such a memory array and shows the overall layout of the regions Z1 and Z2 thus obtained.

The intermediate layer M0 is composed of two different dielectric materials in the regions Z1 and Z2, outside of the connections 10-14 and of the gate structures of the transistors. For example, in the region Z1, the layer M0 is composed of a portion P01 of tantalum oxide (Ta₂O₅), and in the region Z2, it is composed of a portion P02 of silica (SiO₂). Tantalum oxide has a relative dielectric permittivity in the range between 25 and 45 approximately, and silica has a relative dielectric permittivity equal to around 4.2.

Conducting elements of a given SRAM cell which are separated by a gap mainly filled with tantalum oxide exhibit a capacitive interaction between them greater than the interaction that would exist if this gap were only filled with silica. Thus, for the cell C1, enhanced capacitive interactions are present between, on the one hand, the gate link BLTI and, on the other, the section of interconnect SPF, the voltage reference terminal GND and the voltage supply terminal VDD, respectively. These enhanced interactions are represented as capacitor symbols in FIGS. 4a and 5.

In the same way, given that the connections 10-13 are also separated from the gate link BLTI by gaps filled with tantalum oxide, enhanced capacitive interactions also occur between these connections and the gate link BLTI. They are also represented by capacitor symbols in FIGS. 4a and 5.

All of these enhanced capacitive interactions result in a higher capacitance for the gate link BLTI.

For reasons of symmetry of the cell C1, the gate link BLFI of the latter also exhibits enhanced interactions with the terminals and the connections situated close to the link BLFI, and also with the section of interconnect SPT. Its capacitance is therefore also increased. The two nodes of the cell C1, in which electrical charges are contained that depend on the binary value stored in the cell, therefore have capacitances that are increased in an identical fashion. Charges generated in the cell C1 by ionizing radiation are therefore no longer able to alter the stored binary value.

The respective binary information storage states of the cell C2 (FIG. 4a), and also those of other SRAM cells that may be formed on the same substrate (FIG. 4b), can be stabilized in an identical manner against the effects of ionizing radiation. This stabilization is obtained by dividing the intermediate layer, for each of the cells, into portions of dielectric materials having respectively high and low dielectric permittivities in the regions Z1 and Z2. For the sake of clarity, capacitor symbols have not been indicated in FIGS. 4a and 5 to represent the enhanced capacitive interactions in the SRAM cells, apart from the cell C1, but such symbols can be deduced by symmetry from those indicated for the cell C1.

A fabrication process for a memory array comprising SRAM cells according to the invention is now described. In this description, elementary steps of the process which are known from the fabrication of a memory array according to the prior art (FIGS. 1-3) are not discussed in detail. Only a succession of elementary steps allowing the fabrication of a memory array according to the invention will be described.

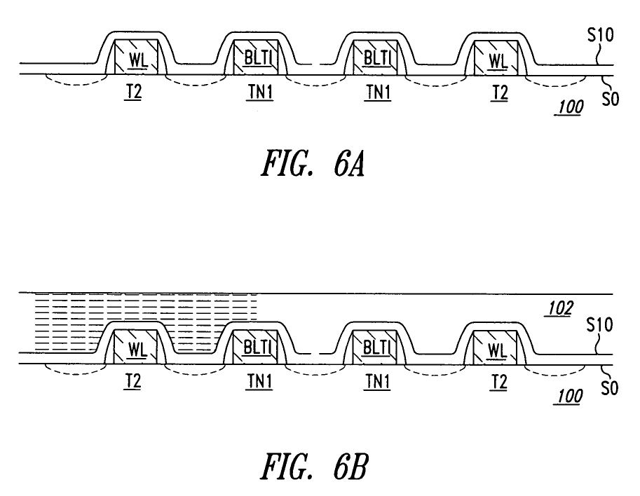

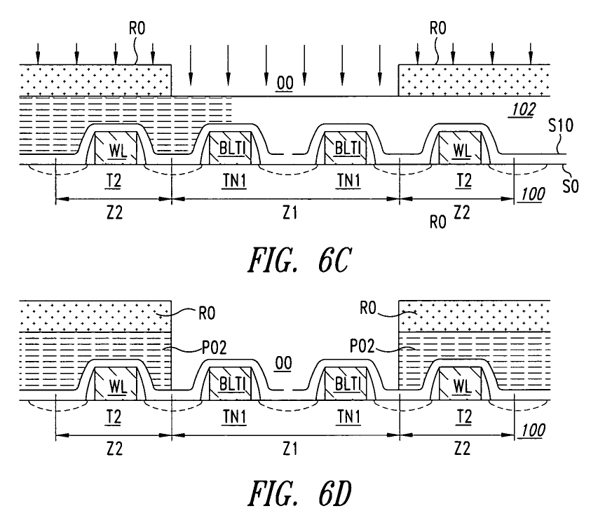

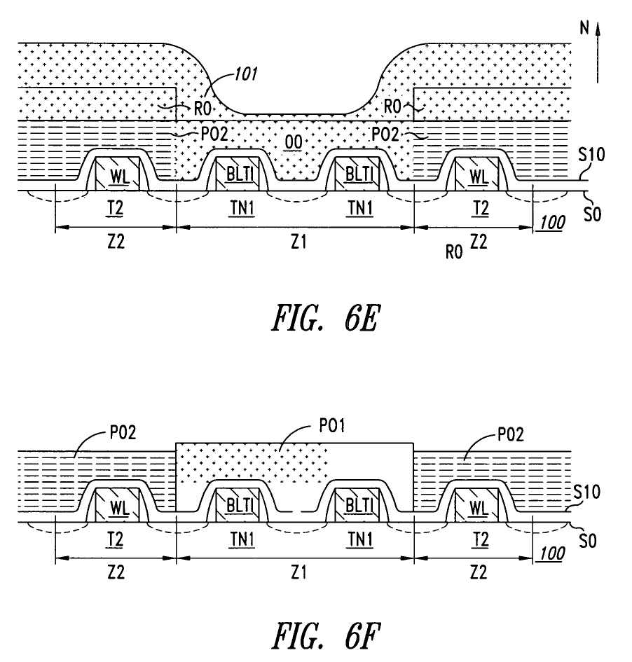

According to FIG. 6a, the transistors of the cells C1 and C2 have been formed on the surface S0 of the substrate 100. In addition, a continuous layer S10, called a stop layer, has been formed so as to cover the surface S0 and the transistors. According to one particular embodiment of the invention, the material of the stop layer S10 is silicon nitride (Si₃N₄).

A layer 102, for example of silica (SiO₂), is then deposited onto the stop layer S10, so as to fill in the gaps between the gates of the transistors. The layer 102 is polished in order to obtain a substantially plane top surface S1 (FIG. 6b). For this purpose, a process of the CMP type (chemical-mechanical polishing), known to those skilled in the art, may be used.

A resist mask R0, which comprises an opening O0 in the region Z1 of the substrate 100, is formed on the layer 102 by photolithography. Thus, the layer 102 is exposed in the region Z1 and is protected by the mask R0 in the region Z2, either side of the region Z1 in the cross-sectional view taken in the plane V-V (FIG. 6c). In order to produce the opening O0 in the resist mask R0, the resist deposited onto the layer 102 is irradiated through a photomask (not shown) that has opaque and transparent regions corresponding to the regions Z1 and Z2.

Subsequently, an anisotropic etching operation is carried out on the layer 102. This is achieved by using a beam of accelerated particles directed against the top surface of the layer 102, such as is shown by the arrows in FIG. 6c. The accelerated particles progressively remove the layer 102 in the region Z1 where the material of the layer 102 is exposed to the etch beam. In the region Z2, the layer 102 is protected by the mask R0 and is therefore not etched. The etching is continued until the stop layer S10 is exposed in substantially all of the region Z1. Portions of the layer 102, referenced P02, then only remain in the region 72 (FIG. 6d).

A layer 101, for example of tantalum oxide (Ta₂O₅), is deposited onto the stop layer S10 in the region Z1 and onto the mask R0 in the region Z2. The layer 101 has a thickness in the direction N equal to at least the thickness of the layer 102. Thus, the layer 101 fills in the gap between the portions P02 at least up to the level of the top surface of the latter (FIG. 6e).

The mask R0 is then removed, for example by dissolving. For this purpose, the memory array can be brought into contact with a solution for removal of the mask R0 through the layer 101. The solution starts by seeping through the cracks in the layer 101, then it dissolves the mask R0 starting from where it seeps through. The portions of the layer 101 deposited onto the mask R0 are therefore removed with the latter. At the end of the process for removal of the mask R0, only a portion P01 of the layer 101 remains in the region Z1.

Finally, a polishing of the top surface of the memory array is carried out, so as to bring the top surfaces of the portions P01 and P02 to substantially identical levels. The polishing conditions are adjusted in order to obtain substantially identical removal rates for silica and tantalum oxide. A step of minimal height, or even no step at all, is then present between the top surfaces of the portions P01 and P02 at the interface of the regions Z1 and Z2.

The intermediate layer M0 is then formed by the portions P01 and P02 being combined.

The fabrication process for the SRAM cells is then continued in a known manner.

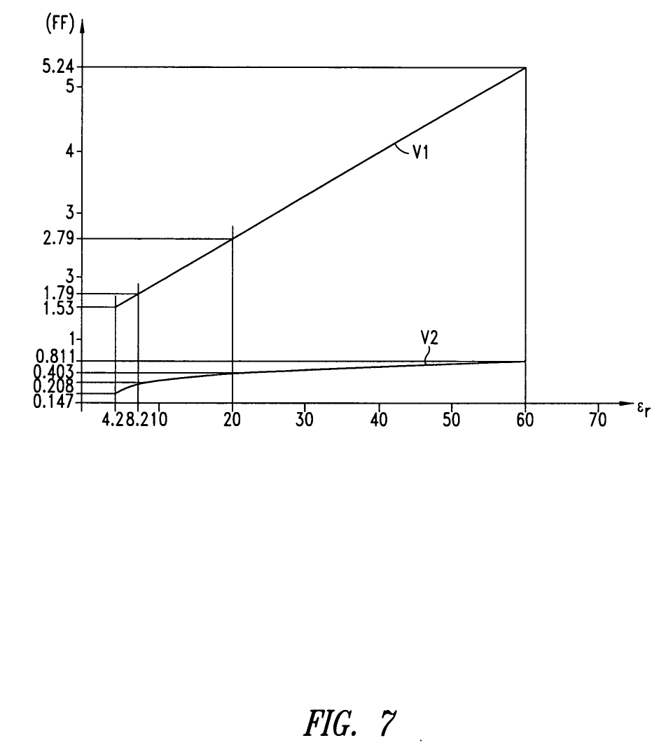

Several embodiments of the invention have been obtained by varying the material of the portion P01. The capacitance of each node BLTI or BLFI of an SRAM cell has been measured for each of these memory arrays and then plotted on the graph in FIG. 7 (curve V1). The various materials used for the portion P01 of the SRAM cells produced correspond to relative dielectric permittivities of around 4.2, 8.2, 20 and 40. These dielectric materials are respectively silica, alumina, lanthanum oxide and tantalum oxide. The vertical axis indicates the various values of measured capacitance in femtoFarads (fF). FIG. 7 shows that the capacitance of each node BLTI or BLFI increases with the value of the dielectric permittivity of the material used for the portion P01. In the same way, the curve V2 illustrates the capacitance measured between the two nodes BLTI and BLFI of the same cell. The points on the curves V1 and V2 associated with the value 4.2 for the dielectric permittivity of the portion P01 correspond to an intermediate layer M0 composed entirely of silica, according to the prior art.

In order to further increase the capacitance of the nodes BLTI and BLFI, the metallization layer M1 can also be divided into several portions. According to FIG. 5, the layer M1 may be composed of a portion P11 in the region Z1 and of a portion P12 in the region Z2, for each SRAM cell outside of the terminals GND, VDD and the sections of interconnect SPT and SPF. The portion P11 can be made of tantalum oxide and the portion P12 can be made of silica. An enhanced capacitive interaction then occurs between the terminals GND and the sections of interconnect SPF and SPT, through the layer M1. This additional enhanced interaction contributes to further increasing the capacitance of the nodes BLTI and BLFI.

In the same manner, the stop layer S10 can also be composed of portions of different materials in the regions Z1 and Z2. The material of the portion S11 of the stop layer S10 in the region Z1 is then advantageously selected to have a higher dielectric permittivity than that of the material of the portion S12 of the stop layer in the region Z2. For example, the material of the portion S11 can be zirconium nitride (Zr₃N₄), and the material of the portion S12 can be silicon nitride (Si₃N₄).

When one of these layers is composed of two portions of different materials, the layer M1 and/or the layer S10 can be formed according to a process analogous to that described above for the layer M0. In particular, the photolithography mask that was used to form the resist mask R0 can also be used to form the composite layers M1 and S0.

It will be understood that many variations may be introduced into the fabrication process of the invention with respect to the description detailed hereinabove. In particular, for each layer M0, M1, S10 that is composed of two portions of different dielectric materials, the deposition order of these materials may be reversed for each layer by using a complementary mask to define the regions Z1 and Z2.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. An integrated electronic circuit comprising:
a substrate having a surface;
active components disposed on the surface of the substrate;
electrical connections disposed within a metallization level situated above the surface of the substrate, the electrical connections being connected to the active components; and
a dielectric material situated between the surface of the substrate and the metallization level, or in the metallization level, the dielectric material having a locally higher value of dielectric permittivity so as to selectively increase a capacitance between certain portions of the active components or of the connections.

2. The circuit according to claim 1, wherein the increased capacitance is present between, first, a gate of a MOS transistor or a connection linking a gate of a MOS transistor and, second, another portion of one of the active components or of connection of the circuit.

3. The circuit according to claim 1, wherein the dielectric material locally exhibits a different chemical composition between the portions of the active components or of the connections of the circuit for which the capacitance is increased.

4. The circuit according to claim 1, wherein the active components include two access transistors and two inverters of a static random access memory cell,
each inverter having an input comprising a gate link between respective gates of two MOS transistors of said inverter, and being connected between a voltage reference terminal and voltage supply terminal, the gate link of each inverter being situated at the surface of the substrate and connected to a section of interconnect disposed within the metallization layer situated above said surface of the substrate, said section of interconnect being furthermore connected to an output of one of the access transistors and to an output of the other inverter,
each access transistor additionally having an input connected to a bit line, and a gate situated at the surface of the substrate and connected to a word line, wherein the dielectric material includes:
an intermediate layer situated between the surface of the substrate and the metallization layer comprising at least a first portion and at least a second portion respectively of a first dielectric material within a first region and of a second dielectric material within a second region, said first dielectric material having a higher dielectric permittivity than a dielectric permittivity of said second dielectric material,
wherein the gate link of each inverter is separated from the voltage reference terminal and from the voltage supply terminal of said inverter, and also from the section of interconnect of the other inverter by respective gaps situated mainly within the first region, and
wherein the gate and the input of each access transistor is situated within the second region.

5. The circuit according to claim 4, wherein the gate link of each inverter is substantially adjacent to the voltage reference terminal and/or to the voltage supply terminal of said inverter, in a projection onto the surface of the substrate.

6. The circuit according to claim 4, wherein each voltage reference terminal or voltage supply terminal comprises a connection that is substantially perpendicular to the surface of the substrate and that extends through the intermediate layer in the first substrate region.

7. The circuit according to claim 4, wherein each gate link of one of the inverters is substantially adjacent to the section of interconnect to which the gate link of the other inverter is connected, in a projection onto the surface of the substrate.

8. The circuit according to claim 4, wherein each interconnect section of an inverter is connected to the output of the corresponding access transistor and to the output of the other inverter by respective connections that are substantially perpendicular to the surface of the substrate and that extend through the intermediate layer in the first region.

9. The circuit according claim 4, wherein the first dielectric material is selected from the list comprising alumina, barium, strontium and titanium oxide, beryllium aluminum oxide, cerium oxide, hafnium oxide, hafnium silicate, lanthanum oxide, silicon nitride, titanium oxide, tantalum oxide, yttrium oxide, zirconium oxide and zirconium silicate, or is a mixture comprising at least one of said materials, and wherein the second dielectric material is selected from the list comprising silica, an organic material and a fluorinated material, or is a mixture comprising at least one of the latter materials.

10. The circuit according to claim 4, wherein the metallization layer itself comprises a first portion and a second portion respectively of a third dielectric material in the first region and of a fourth dielectric material in the second region, said third dielectric material having a higher dielectric permittivity than a dielectric permittivity of said fourth dielectric material.

11. The circuit according to claim 10, wherein the third dielectric material is selected from the list comprising alumina, barium, strontium and titanium oxide, beryllium aluminum oxide, cerium oxide, hafnium oxide, hafnium silicate, lanthanum oxide, silicon nitride, titanium oxide, tantalum oxide, yttrium oxide, zirconium oxide and zirconium silicate, or is a mixture comprising at least one of said materials, and wherein the fourth dielectric material is selected from the list comprising silica, an organic material and a fluorinated material, or is a mixture comprising at least one of the latter materials.

12. The circuit according to claim 4, additionally comprising a stop layer disposed over the gate lines, on at least one side of each of said gate lines opposite to the substrate, and wherein said stop layer itself comprises a first portion and a second portion respectively of a first stopping material in the first region and of a second stopping material in the second region, said first stopping material having a higher dielectric permittivity than a dielectric permittivity of said second stopping material.

13. A memory array comprising:
first and second SRAM cells disposed next to one another on a surface of a substrate, wherein each of the SRAM cells includes:
two access transistors and two inverters, each access transistor having an input connected to a bit line, and a gate situated at the surface of the substrate and connected to a word line, each inverter including:
two MOS transistors connected between a voltage reference terminal and voltage supply terminal;
an input comprising a gate link between respective gates of the two MOS transistors, the gate link of each inverter being situated at the surface of the substrate; and
a section of interconnect connected to the gate link and disposed within a metallization layer situated above said surface of the substrate, said section of interconnect being furthermore connected to an output of one of the access transistors and to an output of the other inverter; and
an intermediate layer situated between the surface of the substrate and the metallization layer comprising at least a first portion and at least a second portion respectively of a first dielectric material within a first region and of a second dielectric material within a second region, said first dielectric material having a higher dielectric permittivity than a dielectric permittivity of said second dielectric material,
wherein the gate link of each inverter is separated from the voltage reference terminal and from the voltage supply terminal of said inverter, and also from the section of interconnect of the other inverter by respective gaps situated mainly within the first region, and
wherein the gate and the input of each access transistor is situated within the second region, wherein the cells are arranged so that the first regions, respectively corresponding to several cells, are contiguous with one another, and so that the second regions, respectively corresponding to certain of the cells, are also contiguous with one another.

14. The memory array of claim 13, wherein the gate link of each inverter is substantially adjacent to the voltage reference terminal and/or to the voltage supply terminal of said inverter, in a projection onto the surface of the substrate.

15. The memory array of claim 13, wherein each voltage reference terminal or voltage supply terminal comprises a connection that is substantially perpendicular to the surface of the substrate and that extends through the intermediate layer in the first substrate region.

16. The memory array of claim 13, wherein each gate link of one of the inverters is substantially adjacent to the section of interconnect to which the gate link of the other inverter is connected, in a projection onto the surface of the substrate.

17. The memory array of claim 13, wherein each interconnect section of an inverter is connected to the output of the corresponding access transistor and to the output of the other inverter by respective connections that are substantially perpendicular to the surface of the substrate and that extend through the intermediate layer in the first region.

18. The memory array of claim 13, wherein the first dielectric material is selected from the list comprising alumina, barium, strontium and titanium oxide, beryllium aluminum oxide, cerium oxide, hafnium oxide, hafnium silicate, lanthanum oxide, silicon nitride, titanium oxide, tantalum oxide, yttrium oxide, zirconium oxide and zirconium silicate, or is a mixture comprising at least one of said materials, and wherein the second dielectric material is selected from the list comprising silica, an organic material and a fluorinated material, or is a mixture comprising at least one of the latter materials.

19. The memory array of claim 13, wherein the metallization layer itself comprises a first portion and a second portion respectively of a third dielectric material in the first region and of a fourth dielectric material in the second region, said third dielectric material having a higher dielectric permittivity than a dielectric permittivity of said fourth dielectric material.

20. The memory array of claim 19, wherein the third dielectric material is selected from the list comprising alumina, barium, strontium and titanium oxide, beryllium aluminum oxide, cerium oxide, hafnium oxide, hafnium silicate, lanthanum oxide, silicon nitride, titanium oxide, tantalum oxide, yttrium oxide, zirconium oxide and zirconium silicate, or is a mixture comprising at least one of said materials, and wherein the fourth dielectric material is selected from the list comprising silica, an organic material and a fluorinated material, or is a mixture comprising at least one of the latter materials.

21. The memory array of claim 13, additionally comprising a stop layer disposed over the gate lines, on at least one side of each of said gate lines opposite to the substrate, and wherein said stop layer itself comprises a first portion and a second portion respectively of a first stopping material in the first region and of a second stopping material in the second region, said first stopping material having a higher dielectric permittivity than a dielectric permittivity of said second stopping material.

22. An integrated electronic circuit fabrication process, comprising the following steps:
forming active components at a surface level of a semiconductor substrate;
depositing, over the substrate surface, at least one layer of a dielectric material;
locally modifying the dielectric material, so as to selectively increase a capacitance between certain portions of active components or of circuit connections; and
forming the circuit connections.

23. The process according to claim 22, wherein the step for modifying the dielectric material comprises a replacement of a portion of said dielectric material with a portion of another material having a different chemical composition, in a region of the layer intended to contain, or to be adjacent to, the portions of the active components or of the connections whose capacitance is to be enhanced.

24. The process according to claim 22, wherein the integrated electronic circuit comprises an integrated static random access memory cell, the process comprising the following steps:
forming, on the surface of the semiconductor substrate, MOS transistors of two inverters, two MOS access transistors and, for each inverter, a link connecting gates of the transistors of said inverter, the active components including the inverters and the MOS access transistors;
forming, over the substrate, a first portion of an intermediate layer in a first region so as to at least partially surround the gate links of the transistors of the inverters in a plane parallel to the surface of the substrate, and a second portion of the intermediate layer in a second region so as to at least partially surround gates and inputs of the access transistors, the first and second portions of the intermediate layer being respectively of a first and a second dielectric material, said first dielectric material having a dielectric permittivity that is higher than a dielectric permittivity of said second dielectric material;
forming, through the intermediate layer, connections that are substantially perpendicular to the surface of the substrate and that respectively extend as far as source or drain regions of the transistors or as far as the gate links; and
forming, over the intermediate layer, a metallization layer incorporating two sections of interconnect each connected to the gate link of the transistors of one of the inverters and to an output of the other inverter, voltage reference terminals, voltage supply terminals and cell access terminals, so that said sections of interconnect and said terminals are in electrical contact with respective connections of the intermediate layer,
the section of interconnect and the voltage reference terminal and voltage supply terminal of each inverter being disposed within the metallization layer so as to be separated from the gate link of the other inverter by respective gaps situated mainly within the first substrate region,
and the cell access terminals being disposed within the metallization layer substantially in a vertical line with the inputs of the access transistors with respect to the surface of the substrate.

25. The process according to claim 24, wherein forming the intermediate layer comprises the following sub-steps:
depositing a layer of the second dielectric material over the surface of the substrate in the first region and in the second region of the substrate;
forming a mask over the layer of the second dielectric material, said mask having an opening corresponding to the first region;
removing the second dielectric material in the first region through the opening in the mask, so that a residual portion of second dielectric material remains in the second region;
forming a portion of the first dielectric material in the first region; and
polishing the respective portions of first and second dielectric materials so that said portions have respective thicknesses that are substantially equal in a direction perpendicular to the surface of the substrate.

26. The process according to claim 24, wherein forming the metallization layer comprises the following sub-steps:
depositing a layer of a third dielectric material over the intermediate layer in the first region and second region of the substrate, on a side of said intermediate layer opposite to the substrate;
forming a first mask over the layer of the third dielectric material, said first mask having an opening corresponding to the first region;
removing the third dielectric material in the first region through the opening in the first mask, so that a residual portion of third dielectric material remains in the second region; and
forming a portion of a fourth dielectric material in the first region,
said fourth dielectric material having a dielectric permittivity that is higher than a dielectric permittivity of said third dielectric material.

27. The process according to claim 26, wherein forming the intermediate layer comprises the following sub-steps:
depositing a layer of the second dielectric material over the surface of the substrate in the first region and in the second region of the substrate;
forming a second mask over the layer of the second dielectric material, said second mask having an opening corresponding to the first region;
removing the second dielectric material in the first region through the opening in the second mask, so that a residual portion of second dielectric material remains in the second region;
forming a portion of the first dielectric material in the first region; and
polishing the respective portions of first and second dielectric materials so that said portions have respective thicknesses that are substantially equal in a direction perpendicular to the surface of the substrate, whereby the first and second masks are formed by photolithography using the same photomask.

28. The process according to claim 24, also comprising, before forming the intermediate layer, covering the surface of the substrate, the transistors and the gate links with a stop layer, said step for covering with the stop layer comprising the following sub-steps:
depositing a layer of a first stopping material over the surface of the substrate in the first region and second region;
forming a first mask over the layer of the first stopping material, said first mask having an opening corresponding to the first region;
removing the first stopping material in the first region through the opening in the first mask, so that a residual portion of first stopping material remains in the second region; and
forming a portion of a second stopping material in the first region,
said second stopping material having a dielectric permittivity that is higher than a dielectric permittivity of said first stopping material.

29. The process according to claim 28, wherein forming the intermediate layer comprises the following sub-steps:
depositing a layer of the second dielectric material over the surface of the substrate in the first region and in the second region of the substrate;
forming a second mask over the layer of the second dielectric material, said second mask having an opening corresponding to the first region;
removing the second dielectric material in the first region through the opening in the second mask, so that a residual portion of second dielectric material remains in the second region;
forming a portion of the first dielectric material in the first region; and
polishing the respective portions of first and second dielectric materials so that said portions have respective thicknesses that are substantially equal in a direction perpendicular to the surface of the substrate, wherein the first and second masks are formed by photolithography using the same photomask.
